(19) United States
(12) Patent Application Publication
(10) Pub. No.: US 2014/0185199 A1
(43) Pub. Date: Jul. 3, 2014

(54) ELECTRONIC DEVICE WITH RELEASABLE CARD HOLDER

(71) Applicants: HON HAI PRECISION INDUSTRY CO., LTD., New Taipei (TW); Fu Tai Hua Industry (Shenzhen) Co., Ltd., Shenzhen (CN)

(72) Inventor: SI-WEI CHEN, Shenzhen (CN)

(21) Appl. No.: 13/931,763

(22) Filed: Jun. 28, 2013

(30) Foreign Application Priority Data
Dec. 29, 2012 (CN) 2012105919530

(51) Int. Cl. H05K 5/02

(52) U.S. Cl. CPC H05K 5/0221
USPC 361/679.01

(57) ABSTRACT

An electronic device includes a housing, a card holder, a latching mechanism, and an elastic member. The housing defines a receiving channel and includes a sidewall. The sidewall defines a slot communicating with the receiving channel and a button hole. The card holder is slidably received in the receiving channel and defines a latching hole. The latching mechanism includes a pushing rod movably received in the button hole, a latching rod slidably received in the housing, and a connecting rod with opposite ends respectively articulated to the pushing rod and the latching rod. The elastic member is received in the housing and is configured to apply a pushing force to the card holder.

### BACKGROUND

1. Technical Field

The present disclosure relates to an electronic device with a releasable card holder.

2. Description of Related Art

Electronic devices, such as mobile phones, may employ one or more electronic cards (e.g., SIM cards, SD cards) for storing information, connecting to the internet, or dialing calls. Thus, it is necessary to provide a card holder for holding/securing the electronic card within the electronic device. Although conventional electronic devices can satisfy this basic requirement, a new type of electronic device with a card holder is still needed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an electronic device according to an exemplary embodiment, the electronic device comprising a card holder and a latching mechanism.

FIG. 2 is a partial view of the electronic device of FIG. 1 with the top cut away.

FIG. 3 is a close-up of the inside of the electronic device, showing the card holder being latched by the latching mechanism.

FIG. 4 is an enlarged view of a portion IV of FIG. 3.

FIG. 5 is similar to FIG. 3, but showing a card holder of the electronic device being released by the latching mechanism.

### DETAILED DESCRIPTION

Embodiments of the present disclosure are described in detail, with reference to the accompanying drawings.

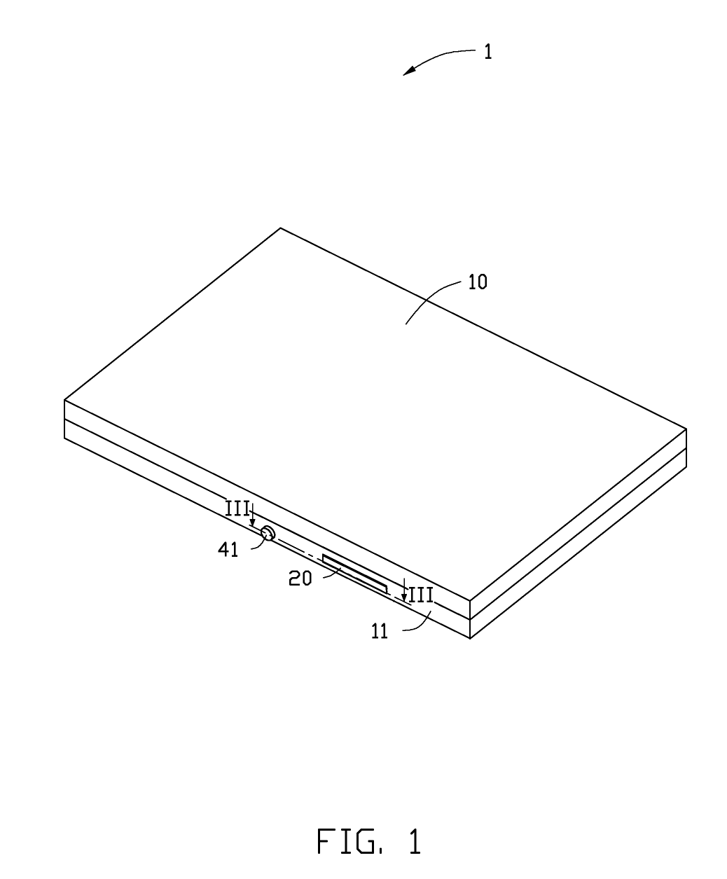

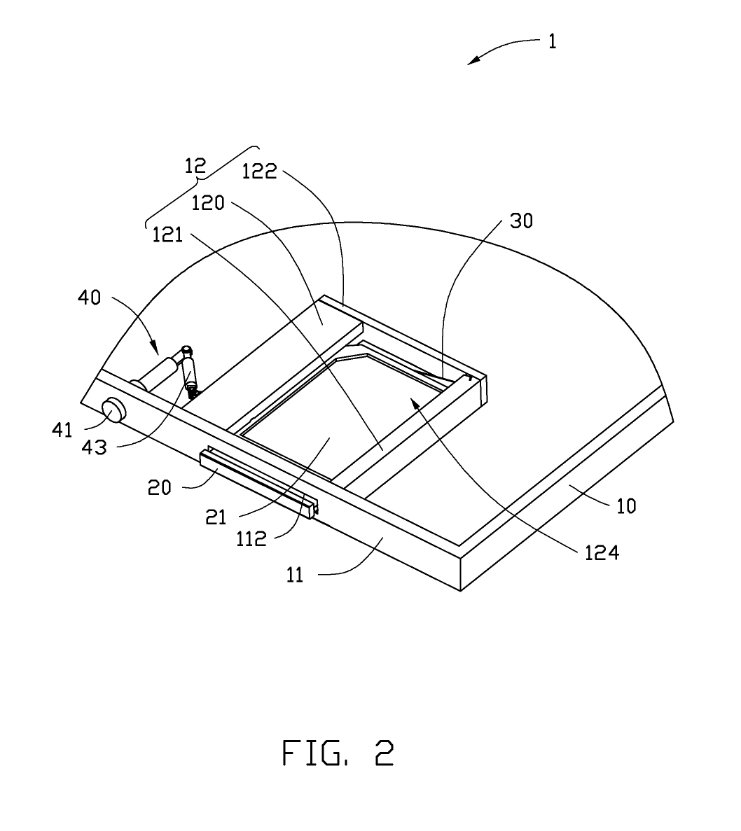

FIGS. 1-2 show an electronic device 1 according to an exemplary embodiment. The electronic device 1 includes a housing 10, a card holder 20, an elastic member 30, and a latching mechanism 40. The electronic device 1 may be a mobile phone, a notebook computer, or the like.

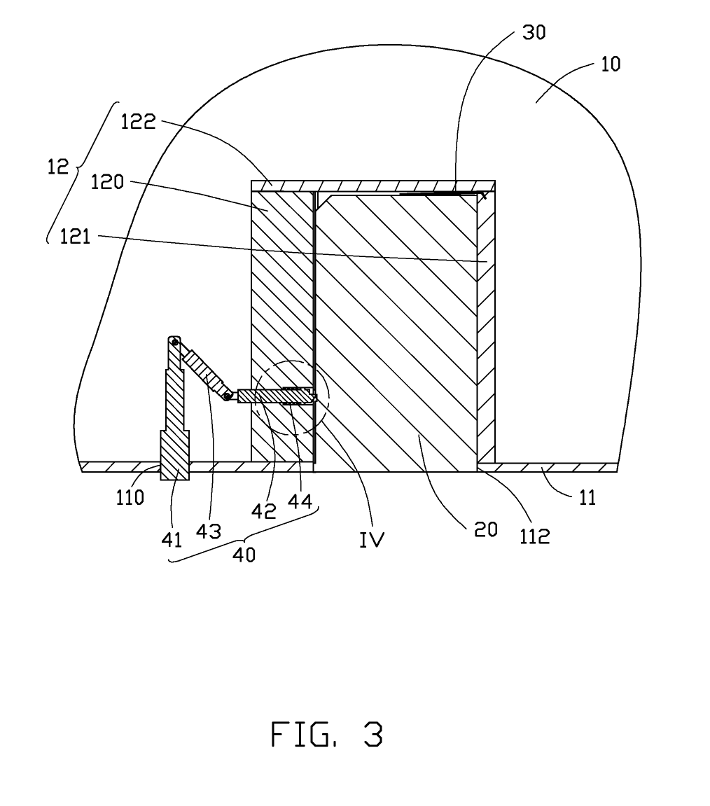

Referring to FIG. 3, the housing 10 includes a sidewall 11 and an internal casing 12 attached to an inner side of the sidewall 11. The sidewall 11 defines a button hole 110 and a slot 112.

The casing 12 includes a first side plate 120, a second side plate 121 parallel to the first side plate 120, and a stopper plate 122 substantially perpendicularly connected to the first side plate 120 and the second side plate 121. The first side plate 120, the second side plate 121, and the stopper plate 122 define a receiving channel 124. The card holder 20 is inserted into the receiving channel 124 through the slot 112. The stopper plate 122 is prevents the card holder 20 from sliding when the card holder 20 slides into position. The first side plate 120 defines a through sliding hole 126 substantially perpendicular to a sliding direction of the card holder 20. The sliding hole 126 includes a first hole portion 1260 and a second hole portion 1262 communicating with each other. A diameter of the first hole portion 1260 is less than that of the second hole portion 1262. A shoulder 1264 is formed between the first hole portion 1260 and the second hole portion 1262.

The card holder 20 is slidably received in the receiving channel 124 of the housing 10. The card holder 20 defines a recess 21 for receiving an electronic card (not shown) and a latching hole 22 in one side. The electronic card may be one of various types of cards such as a secure digital memory card (SD Card) or a subscriber identification module card (SIM Card).

The elastic member 30 is received in the casing 12 and applies an elastic force to the card holder 20 to eject the card holder 20. In one embodiment, the elastic member 30 is a spring tab that is fixed to the second side plate 121 and inclined with respect to the stopper plate 122. When the card holder 20 is inserted into the receiving channel 124 through the slot 112 and in a locked position, the elastic member 30 is elastically deformed toward the stopper plate 122. When the card holder 20 is released by the latching mechanism 40, the elastic member 30 is restored and ejects the card holder 20.

Referring also to FIG. 3, the latching mechanism 40 includes a pushing rod 41, a latching rod 42, a connecting rod 43, and a resilient element 44. The pushing rod 41 is movably received in the button hole 110 of the side plate 11.

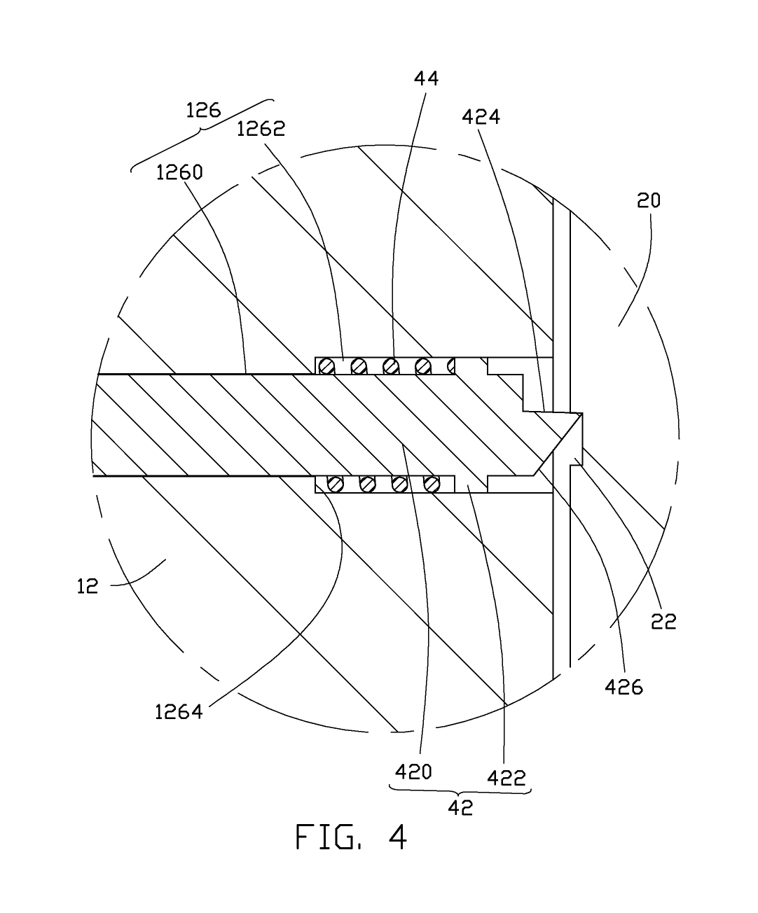

Referring to FIG. 4, the latching rod 42 includes a body 420 and a flange 422 around the body 420. The body 420 extends through the sliding hole 126 of the casing 12, and one end includes a side surface 424 and an end surface 426. The side surface 424 is substantially perpendicular to the sliding direction of the card holder 20. The end surface 426 is inclined with respect to the sliding direction of the card holder 20. The latching rod 42 slides along the sliding hole 126 and inserts into the latching hole 22 of the card holder 20 to latch the card holder 20 within the receiving channel 124 of the housing 10.

Opposite ends of the connecting rod 43 are respectively articulated to the pushing rod 41 and the latching rod 42. The resilient element 44 applies a spring force to the latching rod 42. In the embodiment, the resilient element 44 is a spring coil coiled around the body 420 with opposite ends abutting against the shoulder 1264 of the casing 12 and the flange 422 of the latching rod 42.

Referring to FIG. 3, when the card holder 20 is pushed into the receiving channel 124 of the housing 10, the card holder 20 contacts the end surface 426 of the latching rod 42 and pushes the latching rod 42 into the sliding hole 126 until the latching hole 22 communicates with the sliding hole 126. The resilient element 44 drives the latching rod 42 to move out of the sliding hole 126 and into the latching hole 22, and the side surface 424 contacts a side surface of the latching hole 22, thereby latching the card holder 20 within the receiving channel 124.

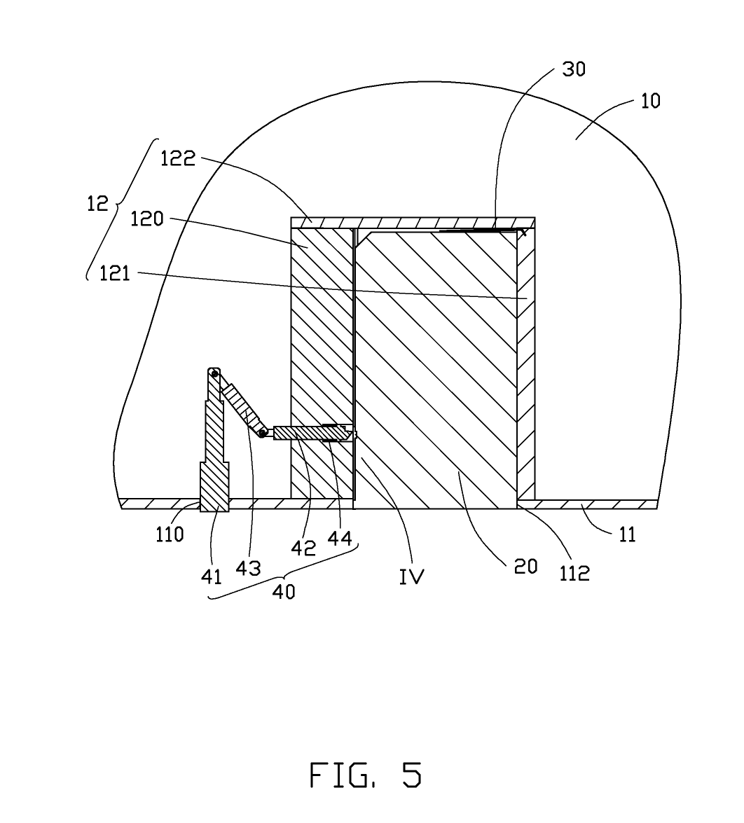

Referring to FIG. 5, when the pushing rod 41 is pushed, the connecting rod 43 is dragged by the pushing rod 41, causing one end to pivot with respect to the pushing rod 41 and another end to pivot with respect to the latching rod 42. Then, the latching rod 42 is dragged by the connecting rod 43 and disengages from the latching hole 22 of the card holder 20 to release the card holder 20, and the elastic member 30 restores and ejects the card holder 20 out of the housing 10. Therefore, the electronic card can be placed into or taken out of the card holder 20.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. An electronic device comprising:
a housing defining a receiving channel and comprising a sidewall, the sidewall defining a button hole and a slot communicating with the receiving channel;
a card holder slidably received in the receiving channel and defining a latching hole therein;
a latching mechanism comprising a pushing rod movably received in the button hole, a latching rod slidably received in the housing, and a connecting rod with opposite ends respectively articulated to the pushing rod and the latching rod; and
an elastic member received in the housing and configured to apply a pushing force to the card holder;
wherein when the card holder is inserted into the receiving channel, the elastic member is elastically deformed by the card holder, and the latching rod engages in the latching hole of the card holder, thereby latching the card holder within the receiving channel;
when the pushing rod is moved along the button hole, the latching rod disengages from the latching hole of the card holder for releasing the card holder, thereby allowing the elastic member to eject the card holder out.

2. The electronic device as described in claim 1, wherein the housing comprises a casing fixedly attached to an inner side of the side wall, and the casing comprises a first side plate and a second side plate parallel to the first side plate, the first and second side plates cooperatively defining the receiving channel therebetween.

3. The electronic device as described in claim 2, wherein the casing comprises a stopper plate substantially perpendicularly connected to the first side plate and the second side plate.

4. The electronic device as described in claim 3, wherein the elastic member is a spring tab fixed to the second side plate and inclined with respect to the stopper plate.

5. The electronic device as described in claim 2, wherein the first side plate defines a sliding hole, the latching rod extends through the sliding hole and is slidable along the sliding hole.

6. The electronic device as described in claim 5, wherein the sliding hole includes a first hole portion and a second hole portion communicating with each other, and a shoulder is formed between the first hole portion and the second hole portion, the latching rod comprises a flange extending therearound, and the latching mechanism further comprises a resilient element positioned between the shoulder and the flange, for applying a spring force to the latching rod.

7. The electronic device as described in claim 6, wherein the resilient element is a spring coil coiled around the latching rod with opposite ends respectively abutting against the shoulder and the flange.

8. The electronic device as described in claim 5, wherein the latching rod comprises an end surface inclined with respect to a sliding direction of the card holder.
